(19) United States
(12) Patent Application Publication
(10) Pub. No.: US 2025/0218953 A1
(43) Pub. Date: Jul. 3, 2025

(54) METHODS AND APPARATUS FOR EMBEDDING INTERCONNECT BRIDGES HAVING THROUGH SILICON VIAS IN SUBSTRATES

(71) Applicant: Intel Corporation, Santa Clara, CA (US)

(72) Inventors: Zhixin Xie, Chandler, AZ (US); Gang Duan, Chandler, AZ (US); Rahul Manepalli, Chandler, AZ (US); Srinivas Pietambaram, Chandler, AZ (US); Andrew Jimenez, Mesa, AZ (US); Andrey Gunawan, Scottsdale, AZ (US); Jung Kyu Han, Chandler, AZ (US); Minglu Liu, Chandler, AZ (US); Shriya Seshadri, Chandler, AZ (US); Yekan Wang, Chandler, AZ (US); Hong Seung Yeon, Chandler, AZ (US); Seyyed Yahya Mousavi, Chandler, AZ (US)

(21) Appl. No.: 18/399,055

(22) Filed: Dec. 28, 2023

(51) Int. Cl. H01L 23/538; H01L 23/00; H01L 23/31; H01L 23/498; H01L 25/065

(52) U.S. Cl. CPC H01L 23/5381; H01L 23/3121; H01L 23/49822; H01L 24/29; H01L 24/45; H01L 25/0652; H01L 2224/29008; H01L 2224/29025; H01L 2224/45005; H01L 2224/4502; H01L 2924/01029; H01L 2924/1431; H01L 2924/1434; H01L 2924/182

(57) ABSTRACT

Example methods and apparatus for embedding interconnect bridges having through silicon vias in substrates are disclosed. An example semiconductor package a bridge die disposed in a recess of an underlying substrate, the bridge die including a via that electrically couples a first contact on a first side of the bridge die and a second contact on a second side of the bridge die, the recess extending to a first surface of the underlying substrate; a bond material to electrically and mechanically couple the first contact and an interconnect of the underlying substrate; and a fill material positioned between the first side of the bridge die and the first surface of the underlying substrate.

### FIELD OF THE DISCLOSURE

This disclosure relates generally to semiconductor devices and, more particularly, to methods and apparatus for embedding interconnect bridges having through silicon vias in substrates.

### BACKGROUND

In many integrated circuit packages, one or more semiconductor dies can be mechanically and electrically coupled to an underlying package substrate. In some instances, the underlying package substrate can include a semiconductor based interconnect bridge embedded therein.

### BRIEF DESCRIPTION OF THE DRAWINGS

FIG. 1 is a cross-sectional view of an example integrated circuitry (IC) package on a printed circuit board (PCB).

FIG. 2 is a cross-sectional view of an example integrated circuit (IC) package including an interconnect bridge implemented in accordance with teachings of this disclosure.

FIGS. 3A-3F illustrate various stages of manufacture of the example IC package of FIG. 2.

FIG. 4 is a cross-sectional view of another example IC package constructed in accordance with teachings of this disclosure.

FIG. 5 is a cross-sectional view of yet another example IC package constructed in accordance with teachings of this disclosure.

FIG. 6 is a flowchart representative of an example method of fabricating the example IC packages of FIGS. 2, 3A-3F, 4 and/or 5.

FIG. 7 is a top view of a wafer including dies that may be included in an IC package constructed in accordance with teachings disclosed herein.

FIG. 8 is a cross-sectional side view of an IC device that may be included in an IC package constructed in accordance with teachings disclosed herein.

FIG. 9 is a cross-sectional side view of an IC device assembly that may include an IC package.

FIG. 10 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Moore's Law, the observation that the number of transistors on an integrated circuit (IC) will double every two years with limited rise in cost, continues to drive scaling for monolithic integrated circuit density. However, as transistor densities increase, the cost and complexity of manufacturing processes to shrink the transistors increases. This can limit accessibility of these devices for customers and limit profits for merchants. To keep Moore's Law going while controlling cost, advanced packaging with increasing levels of integration and partitioned dies has emerged as an important technology. The integration of multiple dies results in tradeoffs between chip and package assembly yield and cost. An important factor to enable the growth of multi-chip package (MCP) offerings is technology for internal connectivity between dies in an IC package. Communication between dies is important for high bandwidth and low latency computation. This is especially true for high performance computation applications such as (but not limited to) data centers.

A previous solution for connectivity between dies in a MCP includes leveraging silicon interposers with metal vias. However, this approach comes at a high cost premium. Instead of using a large silicon interposer, interconnect bridges can be used to connect dies coupled to a package substrate. Interconnect bridges include and/or correspond to semiconductor dies that include compute components, which increase the processing density of integrated circuits including such interconnect bridges. Such interconnect bridges are disposed within cavities of the package substrate and provide features that enable electrical coupling of dies thereto. In some examples, the computer components within interconnect bridges are passive and do not include active semiconductor devices (e.g., transistors). For instance, in some examples, an interconnect bridge contains electrical routing (e.g., traces and connecting vias) fabricated on a semiconductor wafer without any active components. In other examples, interconnect bridges may include at least some active components.

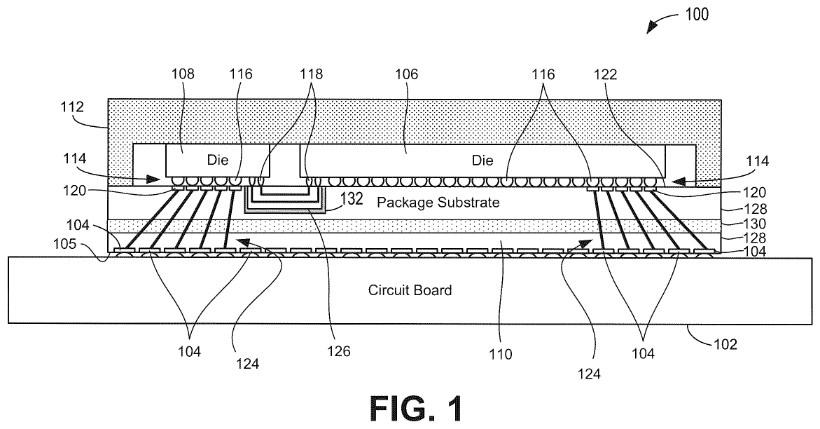

FIG. 1 illustrates an integrated circuit (IC) package 100 (e.g., a semiconductor package). In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path between the interconnects 114 of the dies 106, 108 and the pads 104 mounted to the circuit board 102 that pass through the contact pads 120 and the interconnects 124 provided therebetween. In the illustrated example of FIG. 1, the first die 106 and the second die 108 are coupled via an example interconnect bridge 126 (e.g., also referred to herein as a bridge die, a multi-die interconnect bridge, an embedded interconnect bridge (EMIB), etc.) embedded in the package substrate 110.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within build-up regions 128 on one or both sides of a core 130 the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is an organic substrate or core (e.g., an epoxy-based prepreg layer). In some examples, the substrate core 130 can be a molded or build-up organic substrate. In other examples, the substrate core 130 is a glass substrate or core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In accordance with the present disclosure, glass substrates (e.g., the glass core 130) include at least one glass layer and do not include epoxy and does not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plain view, with the layers above and below the core (e.g., substantially coextensive with the build-up regions 128). The substrate core 130, whether an organic core or a glass core, provides stiffness and mechanical support or strength for the package substrate 110 and the rest of the package 100. Thus, the substrate core 130 is an example means for strengthening the package substrate. In some examples, the thickness of the core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via the interconnect bridge 126 embedded in the package substrate 110, also referred to herein as an embedded interconnect bridge (EMIB). As represented in FIG. 1, core bumps 116 are typically larger than bridge bumps 118. In this example, the interconnect bridge 126 is positioned within an example cavity 132 (e.g., a recess, a trench, etc.) in the inner surface 122 of the package substrate 110. In particular, the interconnect bridge 126 is embedded in the package substrate 110.

Embedded interconnect bridges eliminate or reduce the need for an expensive silicon interposer with TSVs, enabling a lower cost and simpler packaging approach with high-density interconnects between heterogeneous, top dies on a single package. However, while existing interconnect bridges increase the processing density of integrated circuits, this processing density offered by interconnect bridges increases power consumption by a multi-chip package (MCP). Patterning in existing bridge dies provide electronic signals only on a top of the existing interconnect bridge. That is, current interconnect bridge technology is limited to provided electrical signals on the side of the bridge facing towards the dies connected to the bridge. In recent years, there has been an increased need to provide more power to the top dies for higher computing performance.

To compensate for such increased power consumption, example methods and apparatus are disclosed herein to facilitate embedding of an example interconnect bridge having vias that can directly transmit power from a package substrate, through the interconnect bridge, and into one or more top dies. In particular, example interconnect bridges having vias disclosed herein can be connected to the power source of the integrated circuit packages by one or more vias, such as through silicon vias (TSVs), which extend through the base semiconductor material of the interconnect bridges. In doing so, examples disclosed herein improve power delivery from a substrate package to a top die, which further improves chip performance.

Many known interconnect bridges are mounted within a cavity using a die attach film (DAF) followed by lamination of build-up film (e.g., ABF) to insulate and protect the interconnect bridges. However, the DAF process cannot be used with an embedded interconnect bridge having through vias, also referred to herein as an EMIB-T die. In particular, the vias that form interconnects from a PCB or other power source to the top dies need to be mechanically and electrically coupled to the underlying substrate package. The DAF does not provide such electrical interconnection. Rather, in some examples, to communicatively couple the EMIB-T die to the underlying substrate package, a thermal compression bonding (TCB) process is used. In particular, the vias of example interconnect bridges disclosed herein are coupled to interconnects of the underlying substrate package using an electrically conductive material, such as a solder material. For example, bumps can be formed on an exterior surface of the interconnect bridges that serve to electrically couple the interconnect bridge to electrical interconnects (e.g., electrical routing) within the package substrate. The bumps between the interconnect bridge and the underlying package substrate can have a narrow height and/or small bump pitch, which results in gaps between adjacent bumps and/or between the interconnect bridge and the mating surface of the package substrate. Underfilling such gaps and encapsulating example interconnect bridges disclosed herein presents new challenges. A failure to underfill the gaps can degrade the effectiveness of the coupling between the interconnect bridge and the power source of the integrated circuit package.

Examples disclosed herein enable deposition of a fill material under and/or around interconnect bridge dies disclosed herein to reduce (e.g., eliminate) the number of gaps. In other words, examples disclosed herein enable encapsulation of EMIB-T dies disclosed herein within a cavity of a substrate package.

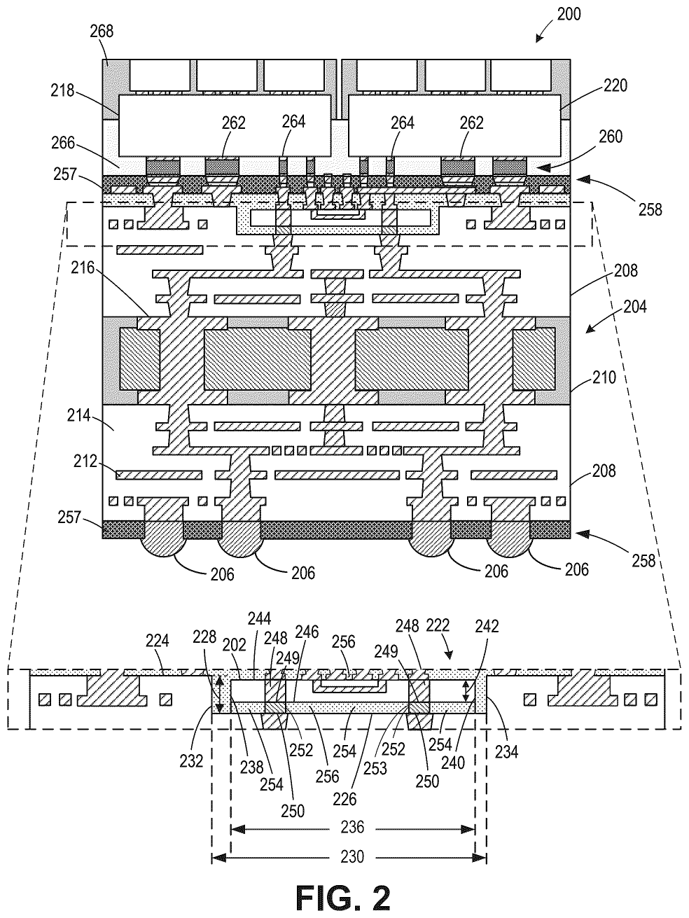

FIG. 2 illustrates another example IC package 200 including an example interconnect bridge 202 (e.g., an interconnect bridge die, a bridge die, an EMIB-T, etc.) embedded in an example package substrate 204 in accordance with teachings of this disclosure. FIG. 2 also illustrates an enlarged view of a portion of the IC package 200 (e.g., the IC package 100 of FIG. 1). Specifically, the enlarged view corresponds to a portion of the package substrate 204 in which the interconnect bridge 202 is embedded. The IC package 200 of FIG. 2 includes an array of example second-level interconnects 206. The second-level interconnects 206 illustrated in FIG. 2 are solder balls (e.g., for a ball grid array arrangement), but any suitable second-level interconnects 206 may be used (e.g., pins in a pin grid array arrangement or lands in a land grid array arrangement). The second level interconnects 206 may be used to conductively couple the IC package 200 to another component, such as a circuit board (e.g., circuit board 102 of FIG. 1), an interposer, or another IC package.

The IC package 200 of FIG. 2 includes example build-up regions 208 (e.g., the build-up regions 128 of FIG. 1) on one or both sides of a package substrate core 210 (e.g., the core 130 of FIG. 1) of the package substrate 204. For example, the build-up regions 208 can include redistribution layers (RDLs) that provide electrical routing through the package substrate 204. For example, the build-up regions 208 can include multiple conductive layers formed of an electrically conductive material 212, which are separated from one another by layers of dielectric material 214. In such examples, traces or routing in the different conductive layers are electrically coupled by conductive (e.g., metal) vias extending between the different conductive layers. The electrically conductive material 212 can include, for example, copper, gold, aluminum and/or any other electrically conductive material(s).

As illustrated in FIG. 2, the core 210 includes vias 216 (e.g., core vias) extending therethrough to define an electrical path between different sides of the core 210. While the core 210 of FIG. 2 includes three vias 216, the core 210 can include less than three vias 216 or more than three vias 216 in other examples. The core vias 216 include an electrically conductive material such as, for example, copper, gold, aluminum and/or any other electrically conductive material(s). In some examples, the core vias 216 include or are defined by a material substantially similar to or the same as the conductive material 212. In some examples, the core vias 216 are formed of a material that is different than the conductive material 212. In some examples, the core vias 216 include multiple layers of both conductive material and non-conductive dielectric materials.

In this example, the IC package 200 includes example semiconductor (e.g., silicon) dies 218, 220 (e.g., the dies 106, 108 of FIG. 1), also referred to herein as top dies. The dies 218, 220 are mounted to the package substrate 204. While the IC package 200 of FIG. 2 includes two top dies 218, 220, the IC package 200 can include one die or more than two dies in other examples. For example, the IC package 200 can include a single, monolithic die and/or disaggregated dies. The dies 218, 220 can provide any suitable type of functionality (e.g., data processing, memory storage, etc.).

As illustrated in the example of FIG. 2, the interconnect bridge 202 is electrically and mechanically coupled to the package substrate 204. The interconnect bridge 202 is positioned in an example cavity 222 (e.g., the cavity 132 of FIG. 1) that extends from a first (e.g., upper) surface 224 of the package substrate 204 to a second (e.g., lower, recessed, etc.) surface 226 of the package substrate 204. The second surface 226 of the package substrate 204 defines a base wall of the cavity 222. The cavity 222 has a depth 228 that extends from the first surface 224 of the package substrate 204 to the second surface 226 of the package substrate 204. Further, the cavity 222 has a width 230 that extends from a first cavity wall 232 defining a first lateral surface of the cavity 222 to a second cavity wall 234 defining a second lateral surface of the cavity 222.

While the example IC package 200 of FIG. 2 includes one interconnect bridge 202, in other examples, the IC package 200 may have more than one interconnect bridge 202. In some examples, multiple interconnect bridges 202 can be positioned with the same cavity 222. In some examples, multiple interconnect bridges 202 can be distributed among multiple cavities 222, with different ones of the cavities 222 having one or more interconnect bridges 202.

The interconnect bridge 202 of FIG. 2 has a width 236 defined by a distance from a first (e.g., lateral) surface 238 (e.g., wall, etc.) of the interconnect bridge 202 to a second (e.g., lateral) surface 240 (e.g., wall, etc.) of the interconnect bridge 202 opposite to the first surface 238. The interconnect bridge 202 of FIG. 2 has a height 242 defined by a distance from a third (e.g., upper) surface 244 (e.g., wall, etc.), that extends between the first and second surfaces 238, 240, to a fourth (e.g., base) surface 246 (e.g., wall, etc.) opposite the third surface 244. The height 242 of the interconnect bridge 202 of FIG. 2 is smaller than the depth 228 of the cavity 222. Further, the width 236 of the interconnect bridge 202 of FIG. 2 is smaller than the width 230 of the cavity 222. In other words, the interconnect bridge 202 is embedded in the cavity 222 of the package substrate 204. In some examples, the depth 228 and/or the width 230 of the cavity 222 is at least partially based on the width 236 and/or the height 242 of the interconnect bridge 202 (e.g., the cavity 222 is dimensioned to house the interconnect bridge 202 and position the interconnect bridge 202 with the third surface 244 approximately adjacent to (e.g., aligned with) the first surface 224 of the package substrate 204).

As illustrated in FIG. 2, the interconnect bridge 202 includes vias 248 (e.g., bridge vias) extending through the interconnect bridge 202. In particular, the bridge vias 248 extend from the third surface 244 of the interconnect bridge 202 to the fourth surface 246 of the interconnect bridge 202. In some examples, the bridge vias 248 may not extend continuously between the third and fourth surfaces 246 of the interconnect bridge 202. Rather, in some examples, the bridge vias 248 may be coupled to electrical tracing or routing in metal layers within the interconnect bridge (e.g., adjacent the third surface 244). While the interconnect bridge 202 of FIG. 2 includes two bridge vias 248, the interconnect bridge 202 can include one bridge via or more than two bridge vias in other examples. The bridge vias 248 define an electrical path through the bridge vias 248 to provide power, from the underlying package substrate 204, to the interconnect bridge 202 and/or to the dies 218, 220 connected to the interconnect bridge 202. Further, the bridge vias 248 define and/or are electrically coupled to contacts (e.g., conductive pads) in the third and/or fourth surfaces 244, 246 of the interconnect bridge 202.

In the illustrated example of FIG. 2, the bridge vias 248 define conductive contacts 249 in the fourth surface 246 of the interconnect bridge 202 to electrically coupled the interconnect bridge 202 and the underlying package substrate 204. In particular, in this example, the contacts 249 correspond to lower ends of the bridge vias 248. However, in other example, the contacts 249 can be coupled to the lower ends of the bridge vias 248. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad, a bump, a pin, or a socket). In this example, the contacts 249 are substantially flush with the fourth surface 246 of the interconnect bridge 202. In some examples, the contacts 249 can be recessed relative to the fourth surface 246 of the interconnect bridge 202. In other examples, the contacts 249 protrude from the fourth surface 246 of the interconnect bridge 202.

The second surface 226 of the package substrate 204 defining the base wall of the cavity 222 includes conductive contacts 250 (e.g., conductive pads, etc.) defined by metal layers positioned within the package substrate 204. For example, the contacts 250 of FIG. 2 correspond to substrate vias positioned relative to the second surface 226 of the package substrate 204. In this example, the contacts 250 are substantially flush with the second surface 226 of the package substrate 204 (e.g., flush with the base wall of the cavity 222). In some examples, the contacts 250 can be recessed relative to the second surface 226 of the package substrate 204. In other examples, the contacts 250 protrude from the second surface 226 of the package substrate 204 (e.g., protrude into the cavity 222). While the package substrate 204 of FIG. 2 includes two contacts 250 in the second surface 226 of the package substrate 204, the package substrate 204 can include one contact or more than two contacts in other examples. In some examples, an amount of the contacts 250 in the second surface 226 of the package substrate 204 corresponds to an amount of the bridge vias 248 extending through the interconnect bridge 202. Further, in some examples, the contacts 250 in the second surface 226 of the package substrate 204 are distributed across the second surface 226 so that different ones of the contacts 250 align with corresponding ones of the bridge vias 248 (and/or aligned with corresponding contacts 249 associated with the bridge vias 248).

The IC package 200 of FIG. 2 includes bond material 252 (e.g., solder, etc.) disposed between the contacts 249 of the interconnect bridge 202 and the contacts 250 of the underlying package substrate 204. The bond material 252 electrically couples the contacts 249 of the interconnect bridge 202 with the contacts 250 in the package substrate 204. The bond material 252 is formed of a conductive bond material that electrically and mechanically couples the bridge vias 248 (e.g., the contacts 249) of the interconnect bridge 202 to the contacts 250 of the underlying package substrate 204. For example, the bond material can include tin, copper, silver, and their alloys, and/or another electrically conductive bond material. In some examples, the bond material 252 undergoes a thermocompression bonding (TCB) process to create the electromechanical connection between the contacts 249 of the interconnect bridge 202 with the contacts 250 in the package substrate 204. For example, the bond material can be formed on ones of the contacts 249 in the interconnect bridge 202 and/or on ones of the contacts 250 in the underlying package substrate 204 as solder bumps. Then, as the contacts 249, 250 are brought together with the solder bumps therebetween under the application of pressure and heat, the solder melts and then resolidifies to define solder joints or bumps 253 (e.g., metallurgical bonds) between the contacts 249, 250.

As illustrated in FIG. 2, a gap 254 forms between the fourth surface 246 of the interconnect bridge 202 and the second surface 226 of the package substrate 204 due to the thickness of the solder joints or bumps 253. The IC package 200 of FIG. 2 includes an example fill material 256 (e.g., an insulation material, etc.) disposed between the fourth surface 246 of the interconnect bridge 202 and the second surface 226 of the package substrate 204 to fill the gaps 254 between the interconnect bridge 202 and the second surface 226 of the package substrate 204. In the illustrated example of FIG. 2, the fill material 256 additionally fills the rest of the cavity 222 to encapsulate the interconnect bridge 202. In other words, the fill material 256 of FIG. 2 is deposited into open areas of the cavity 222 to fill in the space or gaps within the cavity 222 and surround and/or enclose the interconnect bridge 202 and the bond material 252. In some examples, the fill material 256 extends outside and beyond the cavity across the third surface 244 of the interconnect bridge 202 to completely encapsulate the interconnect bridge 202. In some such examples, the fill material 256 also extends across some or all of the first surface 224 of the package substrate 204 that is adjacent to (e.g. aligned with) the third surface 244 of the interconnect bridge 202. The fill material 256 is structured to secure (e.g., fix, maintain, etc.) the interconnect bridge 202 inside the cavity 222. The fill material 256 also provides insulation and mechanical strength to prevent or limit vibration-induced cracking. In some examples, the fill material 256 prevents or reduces crosstalk between adjacent bumps 253.

The fill material 256 of FIG. 2 includes an example molded underfill (MUF) material. In other words, the MUF material fills the gaps 254 between the fourth surface 246 of the interconnect bridge 202 and the second surface 226 of the package substrate 204 and encapsulates the interconnect bridge 202. The MUF material can include, for example, an epoxy mold compound, a build-up dielectric (ABF), a photo-imageable Dielectric (PID) such as polyimide, etc. In some examples, the MUF material includes micro-sized and/or nano-sized particulate fillers. For example, the fillers can provide improved mechanical and/or electrical properties (relative to MUF material without fillers). In some examples, the MUF material includes mixture of fibers and particulate fillers. In some examples, the fillers in the MUF material include silicates, quartz, mica, silicate, titanium dioxide, amorphous silicas, magnesium carbonate, aluminum nitride, alumina, boron nitride, magnesium hydroxide, chalk, limestone, feldspar, barium sulfate, solid or hollow fillers, permanently magnetic metal compounds, and/or alloys or mixtures. In some examples, the fillers in the MUF material can have different geometric shape. In some examples, one or more fillers in the MUF material can be hollow. In some examples, one or more fillers in the MUF material can be hollow. In some examples, the MUF material includes magnetic metal compounds.

The MUF material enables encapsulation, insulation and protection of the interconnect bridge 202. In particular, the MUF material enables encapsulation of the interconnect bridge 202 in one operation (e.g., method, procedure, etc.). A MUF process includes using a molding process to both underfill the gaps 254 and encapsulate the interconnect bridge 202. In some examples, the MUF process involves thermal compression molding, injection molding, and/or lamination and pressing to dispose materials inside of the cavity 222 and encapsulate the interconnect bridge 202.

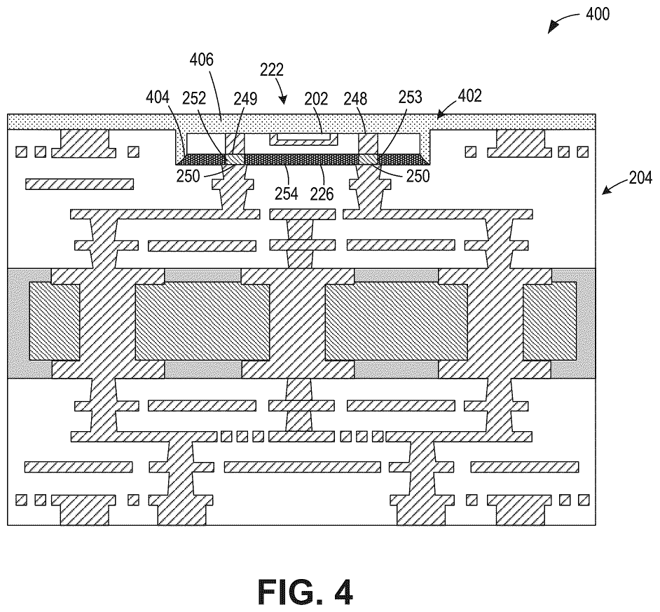

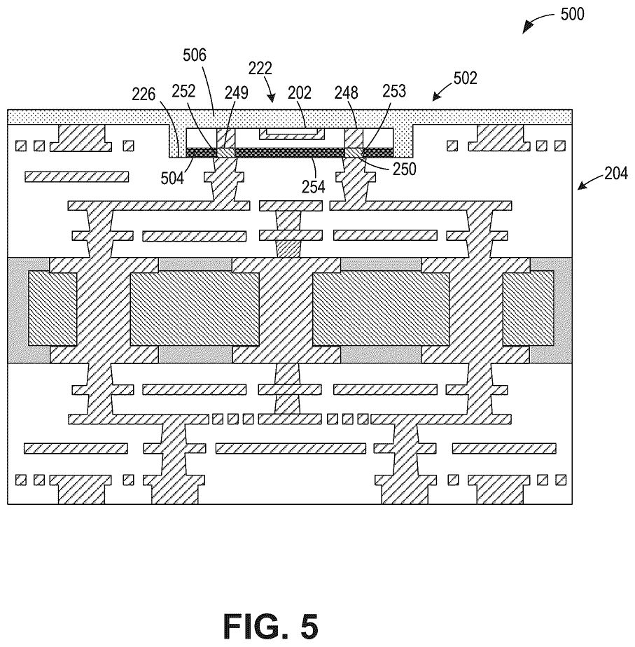

As discussed in further detail below in relation to FIGS. 4 and 5, in some examples, the fill material 256 can include more than one type of fill material. For example, the fill material 256 can include an example first material (e.g., an underfill material), which is to fill the gaps 254 between the fourth surface 246 of the interconnect bridge 202 and the second surface 226 of the package substrate 204, and an example second material (e.g., an encapsulation material) to fill the cavity 222 and cover exposed surfaces within the cavity 222 not occupied by the underfill material.

The IC package 200 of FIG. 2 includes additional (e.g., upper) layers 258 positioned on one or both sides of the package substrate 204 to facilitate the electrical coupling of the package substrate 204 to other components (e.g., the dies 218, 220 and/or a circuit board such as the circuit board 102 of FIG. 1). For example, the additional layers 258 include a solder resist material 257, an electrically conductive material (e.g., copper, aluminum, and/or another electrically conductive material), and/or another material. As illustrated in FIG. 2, the IC package 200 includes example first level interconnects 260 (e.g., the interconnects 114 of FIG. 1) between the top dies 218, 220 and the package substrate 204 to electrically and mechanically couple the top dies 218, 220 and the package substrate 204. As shown in FIG. 2, the first level interconnects 260 of this example include core interconnects 262 (e.g., the core bumps 116 of FIG. 1) and bridge interconnects 264 (e.g., the bridge bumps 118 of FIG. 1). The core interconnects 262 electrically couple the dies 218, 220 and components external to the IC package 200. The bridge interconnects 264 electrically couple different ones of the dies 218, 220 within the IC package 200.

In this example, another underfill material 266 (e.g., a package underfill material) is disposed between the dies 218, 220 and the package substrate 204 (e.g., around the first-level interconnects 260). In this example, a mold compound 268 is disposed around the dies 218, 220. In some examples, the underfill material 266 may be the same as the mold compound 268. Example materials that may be used for the underfill material 266 and the mold compound 268 are epoxy mold materials, as suitable.

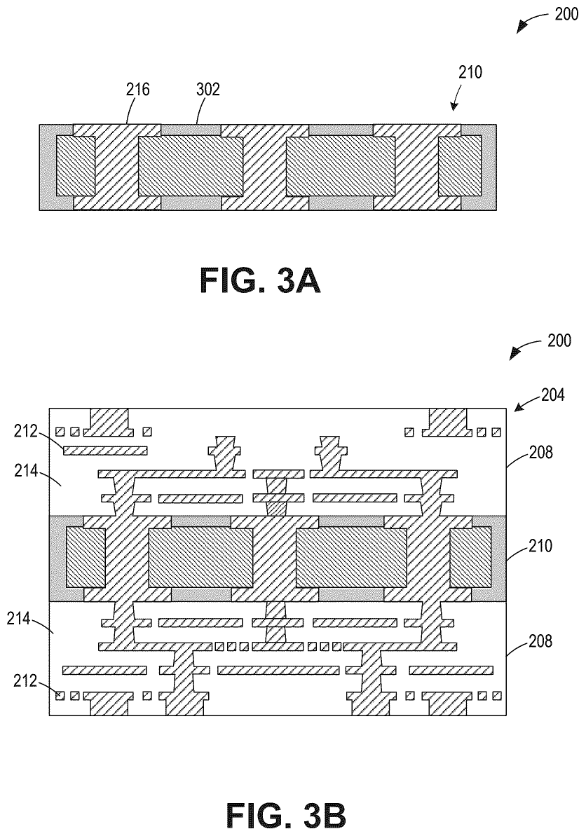

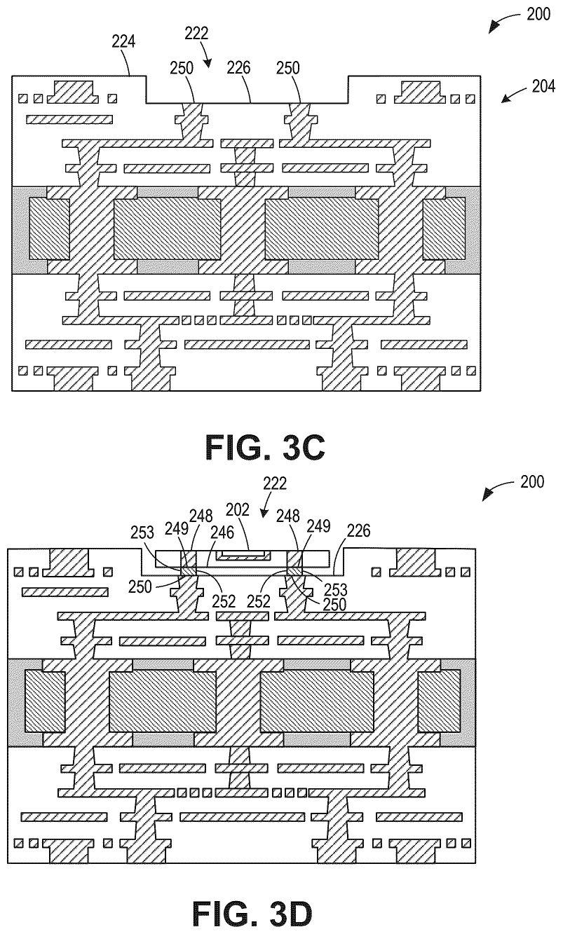

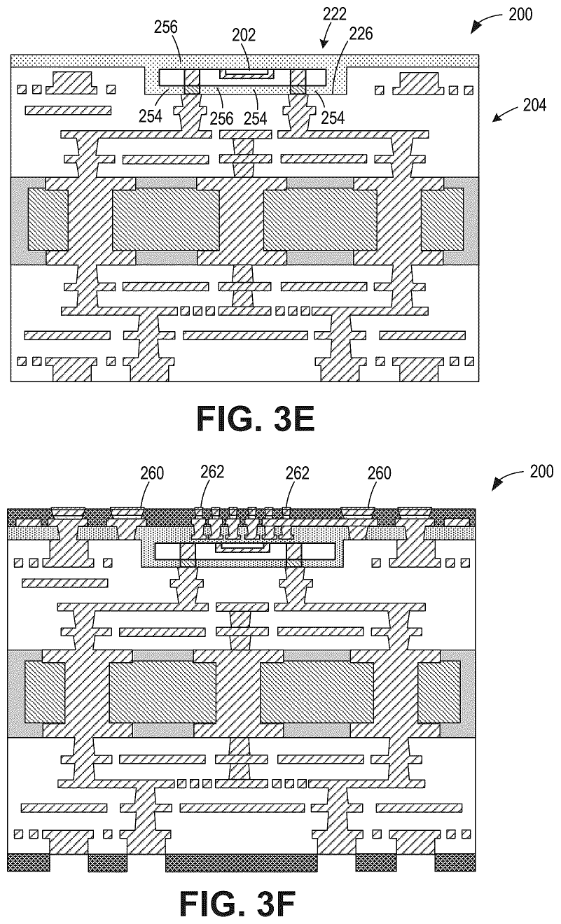

FIGS. 3A-3F illustrate various stages of manufacture of an example IC package having an example interconnect bridge 202 disclosed herein. In particular, FIGS. 3A-3F illustrate an example method to manufacture an example IC package (e.g., the IC package 100 of FIG. 1, the IC package 200 of FIG. 2, etc.) that can have one or more interconnect bridges 202 disclosed herein. For example, FIGS. 3A-3F are cross-sectional illustrations of the example IC package 200 of FIG. 2 at various manufacturing stages.

Turning in detail to the drawings, FIG. 3A illustrates the substrate core 210 of the IC package 200. The core 210 provides mechanical strength and an electrical path between different sides of the core 210 through the core vias 216. In the illustrated example of FIG. 3A, the substrate core 210 is an organic core that is lined with an outer layer 302. In some examples, the outer layer 302 includes an electrically conductive material (e.g., a metal). For example, the outer layers 302 can include copper, gold, aluminum and/or any other electrically conductive material(s). In some examples, the outer layer 302 is attached to the substrate core 210 during the fabrication of the substrate core 210. That is, in some examples, the outer layer 302 can be considered as part of the substrate core 210. In some examples, the outer layer 302 can be added later. In some examples, the outer layer 302 may be omitted from the substrate core 210.

FIG. 3B illustrates the IC package 200 after build-up regions 208 have been formed on either side of the core 210. In particular, FIG. 3B illustrated the IC package 200 after deposition of layers of a conductive material 212 separated from one another by layers of dielectric material 214 and interconnected by electrically conductive vias. In some examples, the metal layers and/or the vias are formed using semi-additive processes building up from the core 210. However, any suitable process can be used in additional or alternative examples.

FIG. 3C illustrates the IC package 200 after formation of the cavity 222. The cavity 222 is generated to provide space for placement of the interconnect bridge 202 (FIG. 2). The cavity 222 extends from the first surface 224 of the package substrate 204 to the second surface 226 of the package substrate 204, which defines the base wall of the cavity 222. In some examples, the cavity 222 is formed by a drilling process (e.g., mechanical drilling, laser drilling, etc.), an etching technique, and/or another suitable method to generate a cavity in a package substrate. The second surface 226 of the package substrate 204 includes the conductive contacts 250 defined by substrate vias positioned relative to the second surface 226 of the package substrate 204. As discussed above, in some examples, the contacts 250 can be recessed relative to the second surface 226 of the package substrate or protrude from the second surface 226 of the package substrate 204 (e.g., protrude into the cavity 222).

FIG. 3D illustrates the IC package 200 after assembly of the interconnect bridge 202 within the cavity 222 such that the second surface 246 of the interconnect bridge 202 faces the second surface 226 of the cavity 222. In particular, FIG. 3D illustrates the IC package 200 after the contacts 249 of the interconnect bridge 202 are coupled to the contacts 250 in the second surface 226 of the package substrate 204 by the bond material 252. For example, a bond material 252 can be positioned on the conductive contacts 250 in the second surface 226 of the underlying package substrate 204 and/or on the contacts 249 of the interconnect bridge 202. As discussed above, in some examples, the contacts 249 can be recessed relative to the interconnect bridge 202 or protrude from the fourth surface 246 of the interconnect bridge 202.

In some examples, a bonding tool (e.g., a pick and place machine) positions the interconnect bridge 202 within the cavity 222 based on visuals on edges and/or fiducials of the interconnect bridge 202 and/or edges and/or fiducials in the cavity 222. For example, the bonding tool can align the interconnect bridge 202 relative to the cavity 222 based on the visuals of the interconnect bridge 202 and/or the visuals of the package substrate 204. In some example, the bonding tool utilizes a machine-based algorithm. When the interconnect bridge 202 is positioned within the cavity 222, a TCB process (e.g., heat and compression) can be applied to melt the bond material 252 and form the bumps 253.

In some examples, a flux material is deposited on the fourth surface 246 of the interconnect bridge 202 prior to placement of the interconnect bridge 202 within the cavity 222. For example, the fourth surface 246 of the interconnect bridge 202 can be dipped in the flux material and then positioned within the cavity 222. In some such examples, after the TCB process, flux residue in the cavity 222 can be removed by a de-flux process. In other such examples, the flux residue can become part of the underfill if using non-clean flux. In some examples, the flux material can be omitted.

FIG. 3E illustrates the IC package 200 after deposition of the fill material 256. In some examples, the fill material 256 can be deposited into open areas of the cavity 222 and cured to secure the interconnect bridge 202 inside the cavity 222. In some such examples, the fill material 256 is a MUF material that can be dispensed to fill the cavity 222, followed by high temperature molding to form the encapsulation. The molding process may include thermal compression molding, injection molding or lamination and pressing. A MUF process enables the underfill and the encapsulation to occur in a single combined operation. In particular, the MUF material can fill the gaps 254 between the interconnect bridge 202 and the second surface 226 of the package substrate 204 and also encapsulate the interconnect bridge 202 in the cavity 222.

The MUF material can be deposited in any suitable form. In some examples, the MUF material is deposited as a sheet (e.g., a relatively thin layer) that can be molded. In some examples, the MUF material is deposited as a granular material. For example, the granular material can be dispensed into the cavity 222 and molded such that the MUF material melts and flows into the open spaces. In some examples, the MUF material is deposited as a liquid material.

As discussed in further detail below in relation to FIGS. 4 and 5, the fill material 256 can include additional or alternative materials in other examples. For example, the fill material 256 can include a capillary underfill (CUF) material, a non-conductive film (NCF), a non-conductive paste (NCP), and/or another fill material 256 that can provide insulation, mechanical strength, and limit or reduce crosstalk.

FIG. 3F illustrates the IC package 200 after additional processes to prepare to attachment of the top dies 218, 220. For example, the FIG. 3F illustrates the IC package 200 after solder resist lamination, via drilling, lithography, and plating processes to form first level interconnects 262, 264 (FIG. 2) to complete the fabrication of a package substrate 204 that can be used as the basis for an IC package (e.g., the IC package 100 of FIG. 1, the IC package 200 of FIG. 2, etc.).

Following completion of the stage of manufacture represented in FIG. 3F, further processing may follow including, but not limited to top die attachment, underfill, overmolding, grinding and solder ball attachment to achieve the final structure as shown in FIG. 2. Thereafter, further processing may follow in any suitable manner.

While an example manner of fabricating an IC package 200 having an example interconnect bridge 202 disclosed herein has been illustrated in FIGS. 3A-3F, one or more of the operations and/or processes illustrated in FIGS. 3A-3F may be combined, divided, re-arranged, omitted, eliminated and/or implemented in any other way. Further still, the example of FIGS. 3A-3F may include processes and/or operations in addition to, or instead of, those illustrated in FIGS. 3A-3F and/or may include more than one of any or all of the illustrated processes and/or steps.

FIG. 4 is a cross-sectional view of a portion of another example IC package 400 constructed in accordance with teachings disclosed herein. The IC package 400 is similar to the IC package 200 of FIGS. 2 and 3A-3F. As such, details of the parts of the IC package 200 of FIGS. 2 and 3A-3F that are common with the parts of the IC package 400 of FIG. 4 will not be described in detail again in connection with FIG. 4. Further, the same reference numbers used for structures shown in FIG. 4 will be used for similar or identical structures in FIGS. 2 and 3A-3F. Further, aspects of the example stages of manufacture represented by FIGS. 3A-3F may be adapted for use in connection with the fabrication of the IC package 400 of FIG. 4.

The IC package 400 of FIG. 4 includes an example interconnect bridge 202 disclosed herein in an example cavity 222 of an example package substrate 204. The IC package 400 also includes bond material 252 between contacts 249 of the interconnect bridge 202 and contacts 250 of the underlying package substrate 204 to electrically couple the interconnect bridge 202 to the package substrate 204. For example, the bond material 252 can electrically and mechanically couple the contacts of the interconnect bridge 202 to contacts 250 of the underlying package substrate 204.

The IC package 400 of FIG. 4 includes example fill material 402 to fill the cavity 222. In particular, the fill material 402 of FIG. 4 includes an example underfill material 404 and an example encapsulation material 406. The underfill material 404 is disposed between the fourth surface 246 of the interconnect bridge 202 and the second surface 226 of the package substrate 204 to fill the gaps 254 between the interconnect bridge 202 and the second surface 226 of the package substrate 204. On the other hand, the encapsulation material 406 fills the cavity 222 to encapsulate the interconnect bridge 202. In particular, the encapsulation material 406 covers exposed surfaces within the cavity 222 not occupied by the underfill material 404. In other words, the fill material 402 is deposited into open areas of the cavity 222 to fill in the space or gaps within the cavity 222 and surround and/or enclose the interconnect bridge 202 and the bond material 252. In some examples, as shown in FIG. 4, the fill material 402 extends beyond and outside of the cavity 222 to cover the upper surface of the interconnect bridge 202 and the package substrate 204. The fill material 402 is structured to secure (e.g., fix, maintain, etc.) the interconnect bridge 202 inside the cavity 222. The fill material 402 provides insulation and mechanical strength to prevent or limit vibration-induced cracking. In some examples, the fill material 402 (e.g., the underfill material 404 in particular) prevents or reduces crosstalk between adjacent bumps 253.

In the illustrated example of FIG. 4, the underfill material 404 and the encapsulation material 406 include different materials. In particular, the underfill material 404 of FIG. 4 includes example capillary underfill (CUF) material. For example, the CUF material can be a liquid that has been disposed to flow into the gaps 254 between the interconnect bridge 202 and the second surface 226 of the package substrate 204 and cured. In particular, due to the capillary effect, the CUF material tends to spread upon deposition to fill the gaps 254. In some examples, the CUF material includes an epoxy resin, an epoxy resin with inorganic fillers, and/or another CUF material.

In this example, the encapsulation material 406 includes a MUF material discussed above and/or other mold materials. In other words, the CUF will be the underfill material 404 and the MUF material acts as the encapsulation material 406 to fill the cavity 222 and encapsulate the interconnect bridge 202. In some examples, the MUF material is deposited after the underfill material 404 has been cured. In other examples, the MUF material is deposited onto the uncured underfill 404, and the underfill material 404 and the encapsulation material 406 are cured together. In some such examples, the underfill 404 and the encapsulation material 406 may partially mix such that there is a not a distinct interface between them. In other examples, a distinct interface may exist between the underfill 404 and the encapsulation material 406 as shown in the illustrated example.

Utilizing different materials for the underfill material and the encapsulation material provides greater flexibility in choosing different CUF materials and mold materials. For example, a flowable CUF material can form good bonding and insulation in relatively small gaps 254 between the interconnect bridge 202 and the underlying package substrate 204. At the same time, the encapsulation material can be selected for improved warpage or mechanical performance. In other words, utilizing different materials for the underfill material and the encapsulation material allows for different combinations of these two materials based on needs of the materials.

Similar to the IC package 200 of FIG. 2, in some examples, a flux material is deposited on the fourth surface 246 of the interconnect bridge 202 prior to placement of the interconnect bridge 202 within the cavity 222. For example, the fourth surface 246 of the interconnect bridge 202 can be dipped in the flux material and then positioned within the cavity 222. In some such example, after the thermocompression bonding process, flux residue in the cavity 222 can be removed by a de-flux process. In other such examples, the flux residue can become part of the underfill if using non-clean flux. In some examples, the flux material can be omitted.

FIG. 5 is a cross-sectional view of a portion of another example IC package 500 constructed in accordance with teachings disclosed herein. The IC package 500 is similar to the IC packages 200, 400 discussed above in relation to of FIGS. 2, 3A-3F and/or 4. As such, details of the parts of the IC packages 200, 400 of FIGS. 2, 3A-3F and/or 4 that are common with the parts of the IC package 500 of FIG. 5 will not be described in detail again in connection with FIG. 5. Further, the same reference numbers used for structures shown in FIG. 5 will be used for similar or identical structures in FIGS. 2, 3A-3F and/or 4. Further, aspects of the example stages of manufacture represented by FIGS. 2, 3A-3F and/or 4 may be adapted for use in connection with the fabrication of the IC package 500 of FIG. 5.

The IC package 500 of FIG. 5 includes an example interconnect bridge 202 disclosed herein in an example cavity 222 of an example package substrate 204. The IC package 500 also includes bond material 252 between contacts 249 of the interconnect bridge 202 and contacts 250 of the underlying package substrate 204 to electrically couple the interconnect bridge 202 to the package substrate 204. For example, the bond material 252 can electrically and mechanically couple the bridge vias 248 of the interconnect bridge 202 and the contacts 250 of the underlying package substrate 204.

The IC package 500 of FIG. 5 includes example fill material 502 to fill the cavity 222. In particular, the fill material 502 of FIG. 5 includes an example underfill material 504 and an example encapsulation material 506 (e.g., the encapsulation material 406 of FIG. 4). The underfill material 504 is disposed between the fourth surface 246 of the interconnect bridge 202 and the second surface 226 of the package substrate 204 to fill the gaps 254 between the interconnect bridge 202 and the second surface 226 of the package substrate 204. On the other hand, the encapsulation material 506 fills the cavity 222 to encapsulate the interconnect bridge 202. In particular, the encapsulation material 506 covers exposed surfaces within the cavity 222 not occupied by the underfill material 504. In other words, the fill material 502 is deposited into open areas of the cavity 222 to fill in the space or gaps within the cavity 222 and surround and/or enclose the interconnect bridge 202 and the bond material 252. In some examples, as shown in FIG. 5, the fill material 502 extends beyond and outside of the cavity 222 to cover the upper surface of the interconnect bridge 202 and the package substrate 204. The fill material 502 is structured to secure (e.g., fix, maintain, etc.) the interconnect bridge 202 inside the cavity 222. The fill material 502 provides insulation and mechanical strength to prevent or limit vibration-induced cracking. In some examples, the fill material 502 (e.g., the underfill material 504 in particular) prevents or reduces crosstalk between adjacent ones of the bumps 253.

In the illustrated example of FIG. 5, the underfill material 504 and the encapsulation material 506 include different materials. In particular, the underfill material 504 of FIG. 5 includes example non-conductive material. In particular, in this example, the underfill material 504 of FIG. 5 includes a non-conductive film (NCF) or a non-conductive paste (NCP). For example, the NCF can be a thin, epoxy film, similar to an adhesive. Similarly, the NCP can include epoxy materials mixed with fillers. However, the NCP is a paste rather than a thin film. In this example, the encapsulation material 506 includes a MUF material discussed above and/or other mold materials.

As discussed above in connection with FIGS. 2, 3A-3F, and/or 4, prior to implementing the thermocompression bonding process to create the solder joints or bumps 253, the fourth surface 246 of the interconnect bridge 202 can be dipped into a flux material and positioned within the cavity 222. After the thermocompression bonding process, the fill material 256, 402 of the IC packages 200, 400 of FIGS. 2, 3A-3F, and/or 4 are deposited. However, unlike the process followed in FIGS. 2, 3A-3F, and/or 4, in the example shown in FIG. 5, the underfill material 504 (e.g., NCF or NCP) can act as a flux material. The non-conductive material corresponding to the underfill material 504 of FIG. 5 can be applied to the fourth surface 246 of the interconnect bridge 202 prior to positioning the interconnect bridge 202 within the cavity 222 and prior to the TCB process. In other words, in some examples, the non-conductive film (NCF) can be deposited (e.g., laminated) onto the fourth surface 246 of the interconnect bridge 202 before the TCB process. Additionally or alternatively, in some examples, the non-conductive paste (NCP) can be deposited (e.g., dispensed) onto the fourth surface 246 of the interconnect bridge 202 before the TCB process. In such processes, there is no need for the separate application (e.g., via dipping) of a flux material because the NCP or the NCF can serve that function. During the TCB process, the NCP or the NCF melts due to the high temperature TCB process. As a result, the NCP or NCF material flows and fills the gaps 254 between the interconnect bridge 202 and the second surface 226 of the package substrate 204.

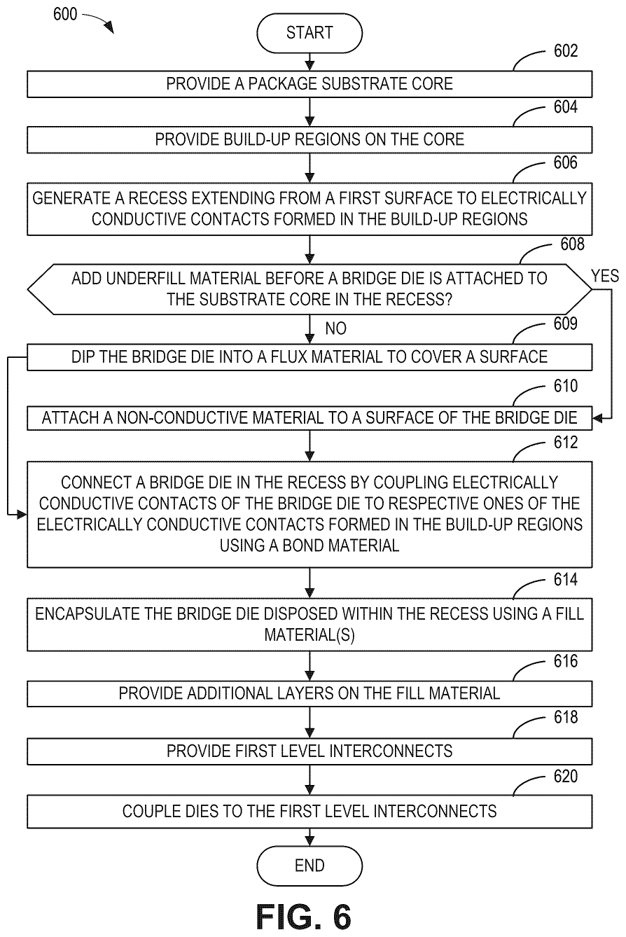

FIG. 6 is a flowchart representative of an example method of fabricating an IC packing having an example interconnect bridge disclosed herein. In particular, FIG. 6 is a flowchart representative of an example method of fabricating the IC package(s) 200, 400, 500 of FIGS. 2, 4, and/or 5 as represented by the example stages of manufacture shown in FIGS. 3A-3F. For purposes of explanation, the example process of FIG. 6 will be described primarily with reference to the IC package(s) 200, 400, 500 of FIGS. 2, 4, and/or 5. However, the following discussion applies similar to any other IC device disclosed herein.

At block 602, the method includes providing a package substrate core 210. The core 210 of the IC package 200, 400, 500 may correspond to any suitable substrate, such as a glass core or an organic core. In some examples, the core 210 includes vias 216 (e.g., core vias) extending therethrough to define an electrical path between different sides of the core 210. In some examples, the substrate core 210 is an organic core that is lined with an outer layer 302. In some examples, the outer layer 302 may be omitted from the substrate core 210.

At block 604, the method includes providing build-up regions 208 on one or both sides of a package substrate core 210. For example, the build-up regions 208 can include redistribution layers (RDLs) that provide electrical routing through a package substrate 204. For example, the build-up regions 208 can include multiple conductive layers formed of an electrically conductive material 212, which are separated from one another by layers of dielectric material 214.

At block 606, the method includes generating a recess (e.g., the cavity 222 of FIG. 2, etc.) extending from a first surface 224 of the package substrate 204 to electrically conductive contacts 250 formed in the build-up regions 208. For example, the contacts 250 can correspond to substrate vias (e.g., defined by metal layers positioned within the package substrate 204) positioned relative to a second surface 226 of the package substrate 204. For example, the generating of the recess 222 can include generating the recess 222 from the first surface 224 of the package substrate 204 to the second surface 226 of the package substrate 204. In some examples, the recess 222 is formed by a drilling process, an etching technique, and/or another suitable method to generate a cavity in a package substrate.

At block 608, the method includes determining whether to add an underfill material 504 before a bridge die 202 (e.g., the interconnect bridge 202 of FIGS. 2, 3A-3F, 4, and/or 5) is attached to the substrate core 210 in the recess 222. When the answer to block 608 is NO, the method advances to block 609 where the bridge die 202 is dipped into a flux material to cover a surface (e.g., the fourth surface 246) of the bridge die 202. Thereafter, the method advances to block 612. When the answer to block 608 is YES, the method includes attaching a non-conductive material to a surface (e.g., the fourth surface 246) of the bridge die 202 (block 610). For example, the underfill material 504 of FIG. 5 can include a non-conductive film (NCF) or a non-conductive paste (NCP). The NCF or the NCP can act as a flux material such that the operation of block 609 becomes unnecessary in this situation.

At block 612, the method includes connecting the bridge die in the recess 222 by coupling electrically conductive second contacts 249 of the bridge die 202 to respective ones of the electrically conductive contacts 250 formed in the build-up regions 208 using a bond material 252. For example, a bond material 252 can be added to the contacts 249 on the bridge die 202 and/or the contacts 250 on the package substrate 204. Upon placement of the bridge die 202 in the recess 222, a TCB process can be implemented to heat and melt the bond material 252 to produce solder joints or bumps 253 that electrically and mechanically coupled the bridge die 202 to the underlying package substrate 204. In some examples, the TCB process additionally melts the underfill material 504 (e.g., the NCP or the NCF), which flows and fills gaps 254 between the bridge die 202 and the second surface 226 of the package substrate 204. In some examples, where a separate flux material was used (added at block 609), the flux residue can be removed following the TCB process through a de-flux process. In some examples, the residue can be retained to be part of the under fill (e.g., if a non-clean flux is used).

At block 614, the method includes encapsulating the bridge die 202 disposed in the recess 222 using fill material(s) 256, 402, 502. In some examples, the fill material 256 shown in FIG. 2 both underfills the bridge die 202 to fill the gaps 254 between the bridge die 202 and the package substrate 204 and encapsulates the bridge die 202. For example, the fill material 256 can include a MUF material that can be deposited to fill the recess 222 and cured. In some examples, the fill material 402, 502 includes an underfill material 404, 504 and an encapsulation material 406, 506 as shown in FIGS. 4 and 5. For example, the underfill material 404 shown in FIG. 4 can include a CUF material) and the encapsulation material 406 shown in FIG. 4 can include a MUF material. In some examples, the MUF material of FIG. 4 is deposited after the underfill material 404 has been cured. In other examples, the MUF material is deposited onto the uncured underfill 404, and the underfill material 404 and the encapsulation material 406 are cured together. In some examples, the underfill material 504 shown in FIG. 5 includes the NCF or the NCF, and the encapsulation material 506 shown in FIG. 5 includes the MUF material. In some such examples, the underfill material 504 is deposited prior to positioning the bridge die 202 in the recess 222, as discussed in relation to block 610. In some such examples, the encapsulation material 506 is deposited after the TCB process to fill areas of the recess 222 not occupied by the underfill material 504.

At block 616, the method includes providing additional layers on the fill material 256, 402, 502. For example, the method can include solder resist lamination, via drilling, lithography, and plating processes. In some examples, a solder resist material 257 can be deposited on one or both sides of the package substrate 204 (e.g., on the fill material 256, 402, 502). In some examples, via drilling, lithography, and plating process can be implemented to provide first level interconnects 260 (e.g., block 618). For example, the first level interconnects 260 can include core interconnects 262 and/or bridge interconnects 262. At block 620, the method includes coupling dies 218, 220 to the first level interconnects 260.

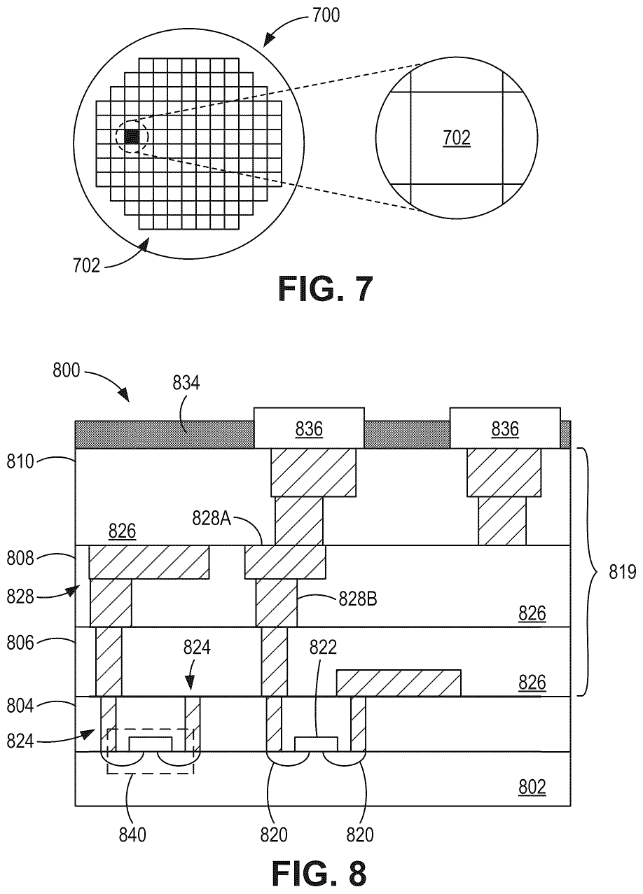

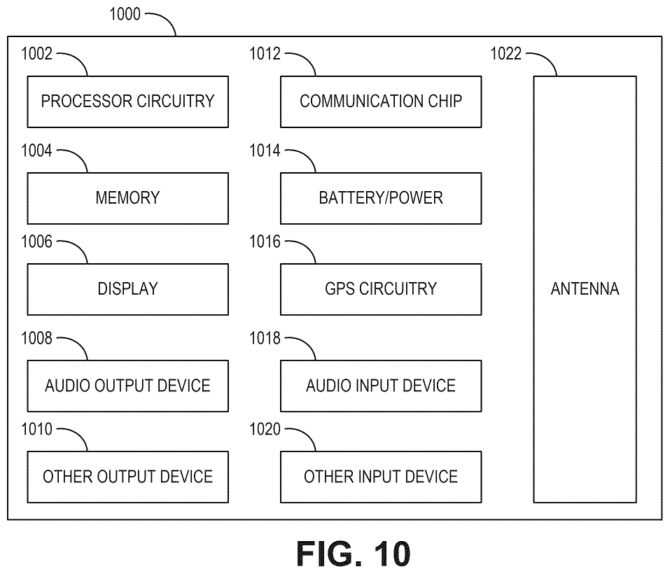

FIG. 7 is a top view of a wafer 700 and dies 702 that may be included in an IC package (e.g., the package 100 of FIG. 1, the package 200 of FIG. 2, the package 400 of FIG. 4, the package 500 of FIG. 5, etc.) whose substrate includes one or more interconnect bridge 202 in accordance with any of the examples disclosed herein. The wafer 700 may be composed of semiconductor material and may include one or more dies 702 having circuitry. Each of the dies 702 may be a repeating unit of a semiconductor product. After the fabrication of the semiconductor product is complete, the wafer 700 may undergo a singulation process in which the dies 702 are separated from one another to provide discrete “chips.” The die 702 may include one or more transistors (e.g., some of the transistors 840 of FIG. 8, discussed below), supporting circuitry to route electrical signals to the transistors, passive components (e.g., traces, resistors, capacitors, inductors, and/or other circuitry), and/or any other components. In some examples, the die 702 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 702. For example, a memory array formed by multiple memory circuits may be formed on a same die 702 as programmable circuitry (e.g., the processor circuitry 1002 of FIG. 10) or other logic circuitry. Such memory may store information for use by the programmable circuitry. The example dies 106, 108, 218, 220 disclosed herein may be manufactured using a die-to-wafer assembly technique in which some dies are attached to a wafer 700 that include others of the dies, and the wafer 700 is subsequently singulated.

FIG. 8 is a cross-sectional side view of an IC device 800 that may be included in an IC package whose substrate includes one or more interconnect bridge 202, in accordance with any of the examples disclosed herein. One or more of the IC devices 800 may be included in one or more dies 702 (FIG. 7). The IC device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some examples, the die substrate 802 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an IC device 800 may be used. The die substrate 802 may be part of a singulated die (e.g., the dies 702 of FIG. 7) or a wafer (e.g., the wafer 700 of FIG. 7).

The IC device 800 may include one or more device layers 804 disposed on or above the die substrate 802. The device layer 804 may include features of one or more transistors 840 (e.g., metal oxide semiconductor field-effect transistors (MOSFETs)) formed on the die substrate 802. The device layer 804 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other examples, at least one of the metal layers that form the gate electrode may simply be a planar layer that is substantially parallel to the top surface of the die substrate 802 and does not include sidewall portions substantially perpendicular to the top surface of the die substrate 802. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of each transistor 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 820 may be formed using one or more alternate semiconductor materials such as germanium or a group III-V material or alloy. In further examples, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the IC device 800.

The interconnect structures 828 may be arranged within the interconnect layers 806-810 to route electrical signals according to a wide variety of designs (in particular, the arrangement is not limited to the particular configuration of interconnect structures 828 depicted in FIG. 8). Although a particular number of interconnect layers 806-810 is depicted in FIG. 8, examples of the present disclosure include IC devices having more or fewer interconnect layers than depicted.

In some examples, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page from the perspective of FIG. 8. The vias 828b may be arranged to route electrical signals in a direction of a plane that is substantially perpendicular to the surface of the die substrate 802 upon which the device layer 804 is formed. In some examples, the vias 828b may electrically couple lines 828a of different interconnect layers 806-810 together.

The interconnect layers 806-810 may include a dielectric material 826 disposed between the interconnect structures 828, as shown in FIG. 8. In some examples, the dielectric material 826 disposed between the interconnect structures 828 in different ones of the interconnect layers 806-810 may have different compositions; in other examples, the composition of the dielectric material 826 between different interconnect layers 806-810 may be the same.

A first interconnect layer 806 (referred to as Metal 1 or “M1”) may be formed directly on the device layer 804. In some examples, the first interconnect layer 806 may include lines 828a and/or vias 828b, as shown. The lines 828a of the first interconnect layer 806 may be coupled with contacts (e.g., the S/D contacts 824) of the device layer 804.

A second interconnect layer 808 (referred to as Metal 2 or “M2”) may be formed directly on the first interconnect layer 806. In some examples, the second interconnect layer 808 may include vias 828b to couple the lines 828a of the second interconnect layer 808 with the lines 828a of the first interconnect layer 806. Although the lines 828a and the vias 828b are structurally delineated with a line within each interconnect layer (e.g., within the second interconnect layer 808) for the sake of clarity, the lines 828a and the vias 828b may be structurally and/or materially contiguous (e.g., simultaneously filled during a dual-damascene process) in some examples.

A third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some examples, the interconnect layers that are “higher up” in the metallization stack 819 in the IC device 800 (i.e., further away from the device layer 804) may be thicker.

The IC device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to other external devices. For example, solder bonds may be formed on the one or more conductive contacts 836 to mechanically and/or electrically couple a chip including the IC device 800 with another component (e.g., a circuit board). The IC device 800 may include additional or alternate structures to route the electrical signals from the interconnect layers 806-810; for example, the conductive contacts 836 may include other analogous features (e.g., posts) that route the electrical signals to external components.

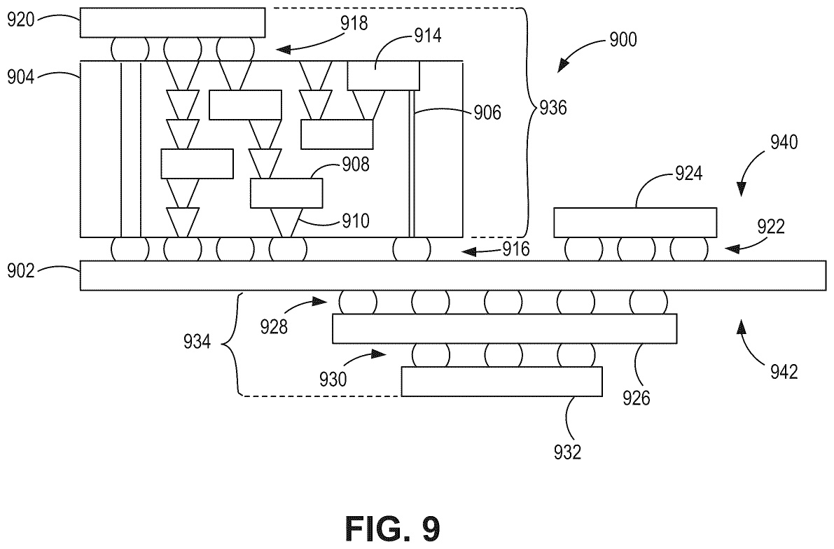

FIG. 9 is a cross-sectional side view of an IC device assembly 900 that may include the example IC packages 100, 200, 400, 500 disclosed herein. In some examples, the IC device assembly corresponds to the example IC packages 100, 200, 400, 500. The IC device assembly 900 includes a number of components disposed on a circuit board 902 (which may be, for example, a motherboard). The IC device assembly 900 includes components disposed on a first face 940 of the circuit board 902 and an opposing second face 942 of the circuit board 902; generally, components may be disposed on one or both faces 940 and 942. Any of the IC packages discussed below with reference to the IC device assembly 900 may take the form of the example IC package 100 of FIG. 1.

In some examples, the circuit board 902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 902. In other examples, the circuit board 902 may be a non-PCB substrate.

The IC device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), male and female portions of a socket, an adhesive, an underfill material, and/or any other suitable electrical and/or mechanical coupling structure.

The package-on-interposer structure 936 may include an IC package 920 coupled to an interposer 904 by coupling components 918. The coupling components 918 may take any suitable form for the application, such as the forms discussed above with reference to the coupling components 916. Although a single IC package 920 is shown in FIG. 9, multiple IC packages may be coupled to the interposer 904; indeed, additional interposers may be coupled to the interposer 904. The interposer 904 may provide an intervening substrate used to bridge the circuit board 902 and the IC package 920. The IC package 920 may be or include, for example, a die (the die 702 of FIG. 7), an IC device (e.g., the IC device 800 of FIG. 8), or any other suitable component. Generally, the interposer 904 may spread a connection to a wider pitch or reroute a connection to a different connection. For example, the interposer 904 may couple the IC package 920 (e.g., a die) to a set of BGA conductive contacts of the coupling components 916 for coupling to the circuit board 902. In the example illustrated in FIG. 9, the IC package 920 and the circuit board 902 are attached to opposing sides of the interposer 904; in other examples, the IC package 920 and the circuit board 902 may be attached to a same side of the interposer 904. In some examples, three or more components may be interconnected by way of the interposer 904.

In some examples, the interposer 904 may be formed as a PCB, including multiple metal layers separated from one another by layers of dielectric material and interconnected by electrically conductive vias. In some examples, the interposer 904 may be formed of an epoxy resin, a fiberglass-reinforced epoxy resin, an epoxy resin with inorganic fillers, a ceramic material, or a polymer material such as polyimide. In some examples, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through-silicon vias (TSVs) 906. The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The IC device assembly 900 may include an IC package 924 coupled to the first face 940 of the circuit board 902 by coupling components 922. The coupling components 922 may take the form of any of the examples discussed above with reference to the coupling components 916, and the IC package 924 may take the form of any of the examples discussed above with reference to the IC package 920.

The IC device assembly 900 illustrated in FIG. 9 includes a package-on-package structure 934 coupled to the second face 942 of the circuit board 902 by coupling components 928. The package-on-package structure 934 may include a first IC package 926 and a second IC package 932 coupled together by coupling components 930 such that the first IC package 926 is disposed between the circuit board 902 and the second IC package 932. The coupling components 928, 930 may take the form of any of the examples of the coupling components 916 discussed above, and the IC packages 926, 932 may take the form of any of the examples of the IC package 920 discussed above. The package-on-package structure 934 may be configured in accordance with any of the package-on-package structures known in the art.

FIG. 10 is a block diagram of an example electrical device 1000 that may include one or more of the example interconnect bridges 202 disclosed herein. For example, any suitable ones of the components of the electrical device 1000 may include one or more of the device assemblies 900, IC devices 800, or dies 702 disclosed herein. A number of components are illustrated in FIG. 10 as included in the electrical device 1000, but any one or more of these components may be omitted or duplicated, as suitable for the application. In some examples, some or all of the components included in the electrical device 1000 may be attached to one or more motherboards. In some examples, some or all of these components are fabricated onto a single system-on-a-chip (SoC) die.

Additionally, in various examples, the electrical device 1000 may not include one or more of the components illustrated in FIG. 10, but the electrical device 1000 may include interface circuitry for coupling to the one or more components. For example, the electrical device 1000 may not include a display 1006, but may include display interface circuitry (e.g., a connector and driver circuitry) to which a display 1006 may be coupled. In another set of examples, the electrical device 1000 may not include an audio input device 1024 (e.g., microphone) or an audio output device 1008 (e.g., a speaker, a headset, earbuds, etc.), but may include audio input or output device interface circuitry (e.g., connectors and supporting circuitry) to which an audio input device 1024 or audio output device 1008 may be coupled.

The electrical device 1000 may include programmable circuitry 1002 (e.g., one or more processing devices). The programmable circuitry 1002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1000 may include a memory 1004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1004 may include memory that shares a die with the programmable circuitry 1002. This memory may be used as cache memory and may include embedded dynamic random access memory (eDRAM) or spin transfer torque magnetic random access memory (STT-MRAM).

In some examples, the electrical device 1000 may include a communication chip 1012 (e.g., one or more communication chips). For example, the communication chip 1012 may be configured for managing wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1012 may operate in accordance with other wireless protocols in other examples. The electrical device 1000 may include an antenna 1022 to facilitate wireless communications and/or to receive other wireless communications (such as AM or FM radio transmissions).

In some examples, the communication chip 1012 may manage wired communications, such as electrical, optical, or any other suitable communication protocols (e.g., the Ethernet). As noted above, the communication chip 1012 may include multiple communication chips. For instance, a first communication chip 1012 may be dedicated to shorter-range wireless communications such as Wi-Fi or Bluetooth, and a second communication chip 1012 may be dedicated to longer-range wireless communications such as global positioning system (GPS), EDGE, GPRS, CDMA, WiMAX, LTE, EV-DO, or others. In some examples, a first communication chip 1012 may be dedicated to wireless communications, and a second communication chip 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display 1006 (or corresponding interface circuitry, as discussed above). The display 1006 may include any visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any device that generates an audible indicator, such as speakers, headsets, or earbuds.

The electrical device 1000 may include an audio input device 1024 (or corresponding interface circuitry, as discussed above). The audio input device 1024 may include any device that generates a signal representative of a sound, such as microphones, microphone arrays, or digital instruments (e.g., instruments having a musical instrument digital interface (MIDI) output).

The electrical device 1000 may include GPS circuitry 1018. The GPS circuitry 1018 may be in communication with a satellite-based system and may receive a location of the electrical device 1000, as known in the art.

The electrical device 1000 may include any other output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include any other input device 1020 (or corresponding interface circuitry, as discussed above). Examples of the other input device 1020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example methods, apparatus, systems, and articles of manufacture to embed interconnect bridges having through silicon vias in substrates are disclosed herein. Further examples and combinations thereof include the following:

Example 1 includes a semiconductor package comprising a bridge die disposed in a recess of an underlying substrate, the bridge die including a via that electrically couples a first contact on a first side of the bridge die and a second contact on a second side of the bridge die, the recess extending to a first surface of the underlying substrate, a bond material to electrically and mechanically couple the first contact and an interconnect of the underlying substrate, and a fill material positioned between the first side of the bridge die and the first surface of the underlying substrate.

Example 2 includes the semiconductor package of example 1, wherein the bond material is a solder material.

Example 3 includes the semiconductor package of example 1, wherein the fill material includes a molded underfill (MUF) material.

Example 4 includes the semiconductor package of example 3, where the MUF material encapsulates the bridge die.

Example 5 includes the semiconductor package of example 3, wherein the MUF material includes at least one of an epoxy mold compound, a build-up dielectric, or a photo-imageable dielectric.

Example 6 includes the semiconductor package of example 3, wherein the MUF material includes particulate fillers.

Example 7 includes the semiconductor package of example 1, wherein the fill material includes a capillary underfill (CUF) material.

Example 8 includes the semiconductor package of example 7, further including an encapsulation material to encapsulate exposed surfaces of the bridge die.

Example 9 includes the semiconductor package of example 1, wherein the fill material includes at least one of a non-conductive film or a non-conductive paste.

Example 10 includes the semiconductor package of example 9, further including an encapsulation material to encapsulate exposed surfaces of the bridge die. a. the semiconductor package of example 1, wherein the bridge die includes a first via and a second via, further including a first die electrically coupled to the first via, and a second die electrically coupled to the second via.

Example 11 includes a semiconductor package comprising build-up layers disposed on a core of a package substrate, a first contact positioned in a recessed surface of a cavity in the build-up layers, a first die having a second contact on a first side of the first die and a third contact on a second side of the first die, the second contact electrically coupled to the third contact through the first die, the second contact bonded to the first contact, the first side of the first die facing towards the recessed surface of the cavity, and an insulation material to fill a gap between the first side of the first die and the recessed surface of the cavity.

Example 12 includes the insulation material extends along lateral edges of the first die and across a second side of the first die, the second die opposite the first die, the lateral edges extending between the first side and the second side.

Example 13 includes the semiconductor package of example 12, wherein a depth of the cavity is larger than a thickness of the first die.

Example 14 includes the semiconductor package of example 12, wherein the insulation material includes at least one of a molded underfill (MUF) material, a capillary underfill (CUF) material, a non-conductive film, or a non-conductive paste.

Example 15 includes the semiconductor package of example 12, wherein the insulation material encapsulates the first die.

Example 16 includes the semiconductor package of example 12, further including a second die electrically coupled to the third contact on the second side of the first die.

Example 17 includes the semiconductor package of example 12, wherein the insulation material includes a first material and a second material, the first material to contact the first side of the first die, the second material to contact all other exposed surfaces of the first die.

Example 18 includes a method comprising providing build-up layers on a core of a package substrate, providing a cavity in the build-up layers, a first surface of the cavity to include a conductive pad, positioning a bridge die in the cavity on the first surface, the bridge die electrically coupled with the conductive pad, and providing a fill material between a first side of the bridge die and the first surface of the build-up layers, the first side of the bridge die facing the first surface.

Example 19 includes the method of example 19, wherein the electrical coupling of the via to the conductive pad including applying a flux material to the bridge die, and implementing a thermocompression bonding process.

Example 20 includes the method of example 20, further including removing the flux material after the thermocompression bonding process.

Example 21 includes the method of example 19, wherein the fill material is a molded underfill (MUF) material, the providing of the MUF material includes at least one of a thermal compression molding process, an injection molding process, or a lamination and pressing process.

Example 22 includes the method of example 22, wherein the MUF material is at least one of a sheet material, a granular material, or a liquid.

Example 23 includes the method of example 22, wherein the MUF material includes at least one of particulate fillers or fibers.

Example 24 includes the method of example 19, wherein the fill material includes a capillary underfill (CUF) material, the providing of the CUF material includes depositing the CUF material, and curing the CUF material.

Example 25 includes the method of example 25, further including depositing an encapsulation material onto surfaces of the bridge die that remain exposed after the curing of the CUF material.

Example 26 includes the method of example 19, wherein the fill material includes a non-conductive material, the non-conductive material including at least one of a non-conductive film or a non-conductive paste.

Example 27 includes the method of example 27, wherein the providing of the fill material includes depositing the non-conductive material, depositing an encapsulation material to surround the bridge die and to contact the non-conductive material, and curing the encapsulation material.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A semiconductor package comprising:
a bridge die disposed in a recess of an underlying substrate, the bridge die including a via that electrically couples a first contact on a first side of the bridge die and a second contact on a second side of the bridge die, the recess extending to a first surface of the underlying substrate;
a bond material to electrically and mechanically couple the first contact and an interconnect of the underlying substrate; and
a fill material positioned between the first side of the bridge die and the first surface of the underlying substrate.

2. The semiconductor package of claim 1, wherein the bond material is a solder material.

3. The semiconductor package of claim 1, wherein the fill material includes a molded underfill (MUF) material.

4. The semiconductor package of claim 3, where the MUF material encapsulates the bridge die.

5. The semiconductor package of claim 3, wherein the MUF material includes at least one of an epoxy mold compound, a build-up dielectric, or a photo-imageable dielectric.

6. The semiconductor package of claim 3, wherein the MUF material includes particulate fillers.

7. The semiconductor package of claim 1, wherein the fill material includes a capillary underfill (CUF) material.

8. The semiconductor package of claim 7, further including an encapsulation material to encapsulate exposed surfaces of the bridge die.

9. The semiconductor package of claim 1, wherein the fill material includes at least one of a non-conductive film or a non-conductive paste.

10. The semiconductor package of claim 9, further including a encapsulation material to encapsulate exposed surfaces of the bridge die.

11. A semiconductor package comprising:
build-up layers disposed on a core of a package substrate;
a first contact positioned in a recessed surface of a cavity in the build-up layers;
a first die having a second contact on a first side of the first die and a third contact on a second side of the first die, the second contact electrically coupled to the third contact through the first die, the second contact bonded to the first contact, the first side of the first die facing towards the recessed surface of the cavity; and
an insulation material to fill a gap between the first side of the first die and the recessed surface of the cavity.

12. The semiconductor package of claim 11, wherein the insulation material extends along lateral edges of the first die and across a second side of the first die, the second side opposite the first side, the lateral edges extending between the first side and the second side.

13. The semiconductor package of claim 11, wherein a depth of the cavity is larger than a thickness of the first die.

14. The semiconductor package of claim 11, wherein the insulation material includes at least one of a molded underfill (MUF) material, a capillary underfill (CUF) material, a non-conductive film, or a non-conductive paste.

15. The semiconductor package of claim 11, wherein the insulation material encapsulates the first die.

16. The semiconductor package of claim 11, further including a second die electrically coupled to the third contact on the second side of the first die.

17. The semiconductor package of claim 11, wherein the insulation material includes a first material and a second material, the first material to contact the first side of the first die, the second material to contact all other exposed surfaces of the first die.

18. A method comprising:
providing build-up layers on a core of a package substrate;
providing a cavity in the build-up layers, a first surface of the cavity to include a conductive pad;
positioning a bridge die in the cavity on the first surface, the bridge die electrically coupled with the conductive pad; and
providing a fill material between a first side of the bridge die and the first surface of the build-up layers, the first side of the bridge die facing the first surface.

19. The method of claim 18, wherein the fill material is a molded underfill (MUF) material, the providing of the MUF material includes at least one of a thermal compression molding process, an injection molding process, or a lamination and pressing process.

20. The method of claim 18, wherein the fill material includes a capillary underfill (CUF) material, the providing of the CUF material includes:
depositing the CUF material; and
curing the CUF material.
